(19) United States
(12) Patent Application Publication
(10) Pub. No.: US 2018/0295707 A1
(43) Pub. Date: Oct. 11, 2018

(54) METHOD OF AND SYSTEM FOR REDUCING OR SUBSTANTIALLY ZEROING ELECTRICAL POTENTIAL

(71) Applicant: Jacob Gitman, Bay Harbor Island, FL (US)

(72) Inventor: MICHAEL BANK, Jerusalem (IL)

(73) Assignee: Jacob Gitman, Bay Harbor Island, FL (US)

(21) Appl. No.: 15/144,330

(22) Filed: May 2, 2016

(51) Int. Cl. H05F 3/02; H01P 9/00; H03H 7/34

(52) U.S. Cl. CPC H05F 3/02; H03H 7/34; H01P 9/00

(57) ABSTRACT

In a method and a system, or so-called nullifier or discharger, for reducing or even zeroing an electrical potential of an electrical system or of an electrical device, an electrically conducting element has one part electrically connectable to an electrical system or an electrical device having an electrical potential, and it extends so that its another part is introduced in a medium other than a layer of Earth.

### BACKGROUND OF THE INVENTION

The present invention relates to the field of electrical systems and devices. More particularly, it relates to methods of reducing an electrical potential and systems for reducing an electrical potential of electrical systems and devices

It is well known that grounding is utilized for reducing and even zeroing an electrical potential of an electric system or an electrical device. It resides generally in that an electrical conductor is used, such that its one part is electrically connected with an electrical system or an electrical device, while its another part is introduced straight into the ground or in other words into a surface layer of Earth. This approach however has numerous disadvantages. In some areas the surfaces layer has sand, stones, or other structures which are not suitable for grounding. Parameters of the surface layer of Earth are not constant, and to a substantial degree they depend on weather. It is often very difficult (or impossible) to get zero potential by grounding in small devices. In many countries conventional grounding by introducing electric current straight into the ground is simply forbidden. There are many cases where ground not available, for example in portable devices or in devices in transport.

### SUMMARY OF THE INVENTION

Accordingly it is an object of the present invention to provide a method of reducing an electrical potential and a system, or a so-called nullifier in case of AC systems or a discharger in case of DC systems, for reducing an electrical potential which avoid the above mentioned disadvantages of the known methods using grounding for reducing an electrical potential of electrical systems and devices.

The present invention can be used in many cases, including but not limited to the following:

For protection of a person from action of an electric current when he/she touches a metal surface, which in case of failure can be under a high voltage.

For zeroing of a potential of a common wire of an electrical device when it is not possible or not economically feasible to connect it with a layer of Earth.

For zeroing a potential of a point of connection of several wires when it is necessary for a normal operation of the device, for example zeroing of a sum of currents of a three-phase system for operation from a zeroed wire or zeroing of a potential of a point of connection of two windings in an inverter based of a transformer without oppositely connected windings.

For zeroing of a potential generated by accumulation of static electricity.

For protection from a lighting discharge.

In keeping with these objects and with others which will become apparent hereinafter one feature of the present invention resides, briefly stated, in a method of reducing an electrical potential of an electrical system or of an electrical device, which includes the steps of electrically connecting one part of an electrically conducting element to an electrical system or an electrical device having an electrical potential, and extending the electrically conducting element so that its another part is introduced in a medium other than a layer of Earth.

When reducing or zeroing of an electrical potential of an electrical system or of an electrical device is carried out according to the method of the present invention, it eliminates the disadvantages of the prior art.

A further feature of the present invention resides in that the extending the electrically conducting element so that its another part is introduced in a medium other than a layer of Earth includes arranging the other part of the electrically conductive element so that it is electrically isolated from the ground of the layer of Earth.

A further feature of the present invention resides in that the extending the electrically conducting element so that its another part is introduced in a medium other than a layer of Earth includes arranging the other part of the electrically conductive element so that it extends in one direction.

A further feature of the present invention resides in that the extending the electrically conducting element so that it's another part is introduced in a medium other than a layer of Earth includes arranging the other part of the electrically conductive element so that it extends in a plurality of directions.

A further feature of the present invention resides in the extending the electrically conducting element which is selected from the group consisting of an electrically conductive wire and an electrically conductive rod.

It is known that in existing grounding where an electrically conductive rod introduced into a layer of Earth is used, many currents flow. These current are detected at a distance of more than 10 m from the rod, or in other words at a distance which is much shorter than a quarter of a wave at frequencies 50 or 60 Hz.

It is well known that a monopole with a length much shorter than a quarter of a wave length has a resistance to radiation close to zero. The monopole is used in the present invention for reducing a potential substantially to zero. Since such a monopole has a capacitive resistance, several monopoles connected to a point which requires zeroing have lower capacitive resistance. It is even lower and even equal to zero when it is compensated by an inductance connected in series with to the point which requires zeroing of signal, whose potential needs to be reduced to zero.

A further feature of the present invention resides in extending the electrically conducting element provided with an inductance between its one part and it's another part.

A further feature of the present invention resides in extending the electrically conducting element which includes a delay line which can be an inverter (phase-shifter in form of a transformer with oppositely connected windings, wherein a point of connection of these winding needs zeroing. For systems and devices operating on one high frequency, the inverter can be formed as a delay line shifting a phase of the electric current by 180 degrees or a number of 180 degrees.

A further feature of the present invention resides in extending the electrically conducting element so that it's another part is introduced in a medium other than a layer of Earth and including ground, or grains of a semiconducting material which can be composed of sand particles.

According to the present invention, a system is also proposed for reducing or even zeroing an electrical potential of an electrical system or of an electrical device, which includes an electrically conducting element which comprises one part electrically connectable to an electrical system or an electrical device having an electrical potential, and extends so that its another part is introduced in a medium other than a layer of Earth.

A further feature of the present invention resides in that the electrically conducting element extends so that its another part is introduced in a medium other than a layer of Earth and is electrically isolated from the ground of Earth.

A further feature of the present invention resides in that the electrically conducting element is configured so that its another part is introduced in a medium other than a layer of Earth and it extends in one direction.

A further feature of the present invention resides in that the electrically conducting element is configured so that it's another part is introduced in a medium other than a layer of Earth and is arranged so that the other part of the electrically conductive element extends in a plurality of directions.

A further feature of the present invention resides in that the electrically conducting element is an element selected from the group consisting of an electrically conductive wire and an electrically conductive rod.

A further feature of the present invention resides that the electrically conducting element has a length substantially much shorter than a quarter electrical wavelengths of an electrical current whose potential is zeroing.

A further feature of the present invention resides in that the electrically conducting element provided with an inductance between its one part and its another part.

A further feature of the present invention resides in that the electrically conducting element includes a delay line shifting a phase of the electric current by 180 degrees or odd number of 180 degrees.

A further feature of the present invention resides the electrically conducting element is configured so that its another part is introduced in a medium which is other than a ground of the layer of Earth and includes grains of a semiconducting material which can be composed of sand particles.

A further feature of the present invention resides in the electrically conducting element as a discharger to be used in direct current systems which is a discharger, which is formed as a hollow pipe-like rod with a size allowing a discharge of static electricity.

The novel features of the method and system according to the present invention are set forth in particular in the appended claims.

The invention itself however both as to its construction and manner of operation will be best understood from the following description of the preferred embodiments, which is accompanied by the following drawings.

### BRIEF DESCRIPTION OF THE DRAWINGS

FIG. 1 of the drawings is a view schematically showing a current distribution in a system for reducing or zeroing an electrical potential with the use of a conventional grounding.

FIG. 2 is a view showing a system for reducing and even substantially zeroing an electrical potential according to one embodiment of the present invention;

FIG. 3 is a view showing a system for reducing and even substantially zeroing an electrical potential according to a further embodiment of the present invention;

FIG. 4 is a view showing a scheme of a system for reducing and even substantially zeroing an electrical potential according to a further, embodiment of the present invention;

FIG. 5 is a view showing a structural implementation of a system for reducing and even substantially zeroing an electrical potential according to a further embodiment of the present invention;

FIG. 6 is a view showing a example of an actual implantation of a system for reducing and even substantially zeroing an electrical potential according to a further embodiment of the present invention;

FIG. 7 is a view showing a system for reducing and even substantially zeroing an electrical potential according to a further embodiment of the present invention;

FIG. 8 is a view showing a single frequency system for reducing and even substantially zeroing an electrical potential according to a further embodiment of the present invention;

FIG. 9 is a view showing a simulation of a single wire electric line and results of using a system for reducing and even substantially for zeroing an electrical potential according to the present invention;

FIG. 10 is a view showing a simulating system for reducing and even substantially zeroing an electrical potential according to a further embodiment of the present invention;

FIG. 11 is a view an electrical scheme for simulation of operation of a system for reducing and even substantially zeroing an electrical potential with capacitance compensation according to the present invention.

FIG. 12 is a view showing simulation of results of operation of a system for reducing and even substantially zeroing an electrical potential without capacitance compensation according to the present invention;

FIG. 13 is a view showing a system for reducing and even substantially zeroing an electrical potential of DC according to a further embodiment of the present invention;

FIG. 14 is a view showing simulation of results of operation of a system for reducing and even substantially zeroing an electrical potential of DC

FIG. 15 is a view showing an electrically conducting element in form of a hollow cylindrical pipe-shaped rod with projections on its surface.

### DESCRIPTION OF PREFERRED EMBODIMENTS

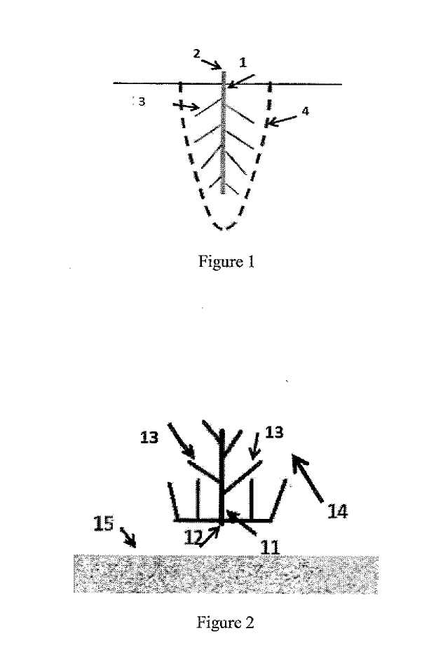

As shown in FIG. 1, a current distribution in a conventional system for reducing and even substantially zeroing an electrical potential of electrical systems and devices includes an electrically conducting element 1 formed for example as a rod. It has one part 2 electrically connectable to a not shown electrical system or an electrical device having an electrical potential, and it extends so that one of currents of its another part 3 is introduced in a medium 4 which is a ground or a layer of Earth. This is a well know grounding of electrical systems and devices. Electrical current flows through the electrically conducting element 1 and from it through in multiple directions in the ground for a limited distance.

FIG. 2 shows a new system for reducing and even substantially zeroing an electrical potential of electrical systems and devices according to one embodiment of the present invention. It includes an electrically conducting element 11 formed for example as a rod. The rod has one part 12 electrically connectable to a not shown electrical system or an electrical device having an electrical potential, and it extends so that two other parts 13 are introduced in a medium 4 which is not a ground or a layer of Earth. The another part 13 is introduced in a medium 14 which is in particular air. It is provided with a plurality of electrically conducting lines or wires 13 which are electrically conductively connected with it. The electrical potential of the electrical system or an electrical device is reduced or even zeroes by discharging it into air. This new system for reducing and even substantially zeroing an electrical potential of electrical systems and devices is formed substantially as an antenna located above but not connected to the ground 15.

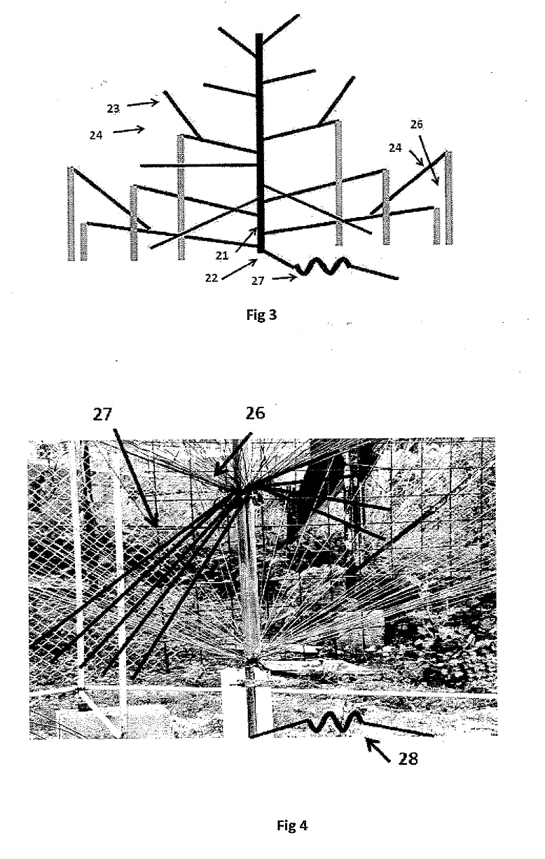

FIG. 3 shows another embodiment of the new system for reducing and even substantially zeroing an electrical potential of electrical systems and devices. It includes an electrically conducting element 21 formed for example as a rod. The rod has one part 22 electrically connectable to a not shown electrical system or an electrical device having an electrical potential, and it extends so that at least its another part 23 is introduced in a medium 24 which is not a ground or a layer of Earth. The another part 23 is introduced in the medium 24 which is in particular air. It is connected at its upper end with one end of a plurality of electrically conducting lines or wires 25 which are electrically conductively connected with it. The lines or wires 25 can extend horizontally or at angles to a horizontal plane. The other ends of the electrically conductive wires 25 are connected with electrically non-conductive rods 26 which are supported on the ground or the layer of Earth. The part 22 is electrically connected with a compensating inductor 27.

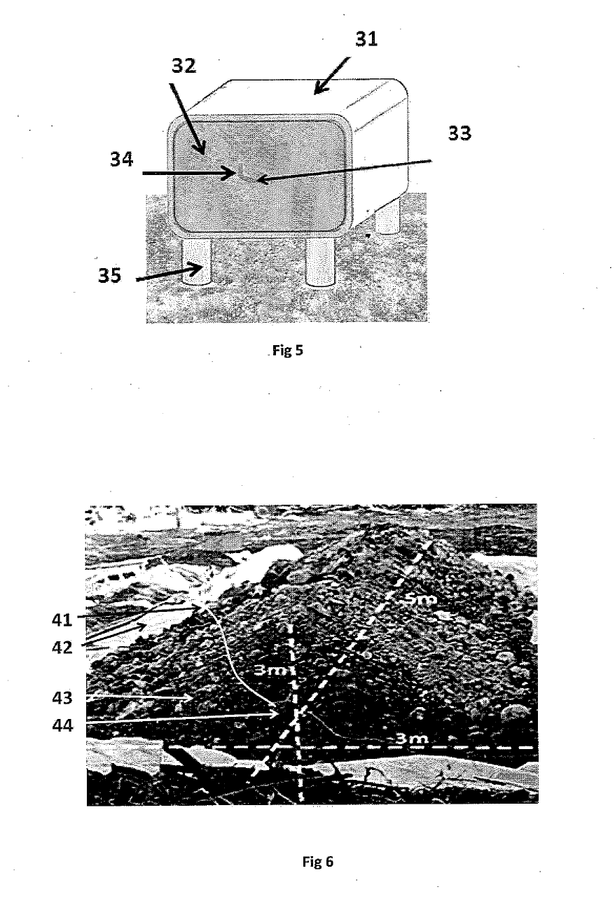

FIG. 4 shows a practical realization of the new system according to the present invention, formed by a plurality of interconnected monopoles 27, used for reducing or even substantially zeroing an electrical potential of a single-wire electrical energy transmission system. The components of the new system for reducing and even substantially zeroing an electrical potential which are shown in FIG. 4 and correspond to the components of the system of FIG. 3 are identified with the same reference numerals. Electrical potential of the single-wire electrical energy transmission system 27 is reduced or even substantially zeroes when it is connected with the new system for reducing and even substantially zeroing an electrical potential according to the embodiment of the present invention shown In FIGS. 3 and 4. In this embodiment a compensating inductance 28 can be provided at the entrance of the system for reducing and even substantially zeroing an electrical potential.

FIG. 5 shows another embodiment of the new system for reducing and even substantially zeroing an electrical potential of electrical systems and devices. It includes an electrically conducting element 33 formed for example as a rod. The rod has one part 34 electrically connectable to a not shown electrical system or an electrical device having an electrical potential, and it extends so that at least its another part 33 is introduced in a medium 32 which is not a ground or a layer of Earth. The another part 33 is introduced in the medium 32 which is in particular ground confined in a box 31 which is supported on the ground or layer of Earth through electrically non-conductive legs 35.

FIG. 6 shows another embodiment of the new system for reducing and even substantially zeroing an electrical potential of electrical systems and devices. It includes an electrically conducting element formed for example as a rod. The rod has one part 44 electrically connectable to a not shown electrical system or an electrical device having an electrical potential, and it extends so that at least its another part is introduced in a medium 43 which is not a ground or a layer of Earth. The another part is introduced in the medium 44 which is in particular ground located in a ditch and confined in an electrically insulating fabric 42 which non-conductively separates the medium 41 from a layer of Earth.

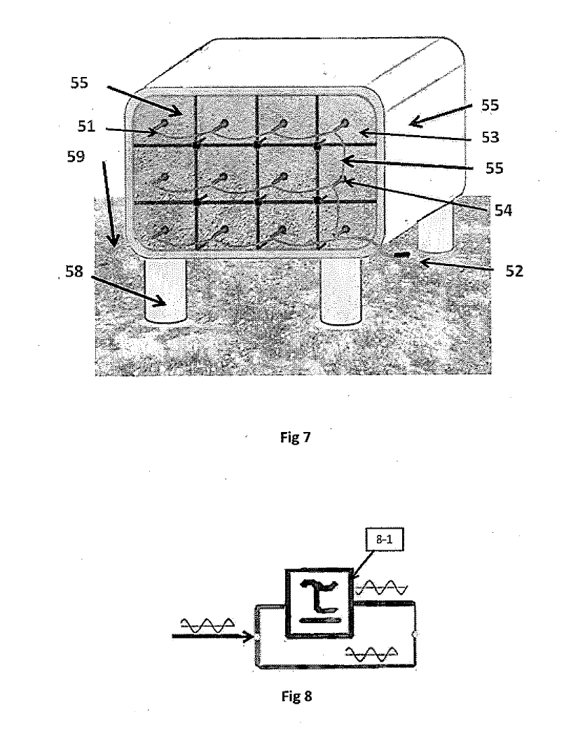

FIG. 7 shows another embodiment of the new system for reducing and even substantially zeroing an electrical potential of electrical systems and devices. It includes an electrically conducting element 51. It has one part 52 electrically connectable to a not shown electrical system or an electrical device having an electrical potential. It extends so that at least its another part 53 is connected with a plurality of electrically conductive rods 54 interconnected by a plurality of electrically conductive wires 55 in parallel connection and introduced in a medium 56 which is not a ground or a layer of Earth. The medium 56 is in particular ground confined in a box 57 which is supported on the ground or layer of Earth 59 through electrically non-conductive legs 58.

FIG. 8 can help to explain principle of a resonance system or a so-called nullifier working. If desired potential signal zeroing on one frequency, this signal can be connected to the same signal, but it must be shifted in phase by 180 degrees. In other words it is possible to add to +A number −A. The change from + to − of AC corresponds to a phase changing by 180 degrees. The phase shift can be performed using a delay line 8-1 to half the wavelength. Clearly, resonant nullifier will work for all odd harmonics. It is evident from the fact that the required phase shift is obtained also in the case where the delay is equal to 1.5, 2.5 and so forth of the wavelength.

FIG. 9 is shown scheme of simulation single line system and results by using resonance nullifier 71 in FIG. 8. Delay line 72 corresponds to line length 300 km. The simulation results in 74, 75 and 76 show that all the currents in the system equal 1 mA and correspond to Ohm's law and that zeroing in the normal and in the resonance nullifiers occur correctly like a common grounding 72.

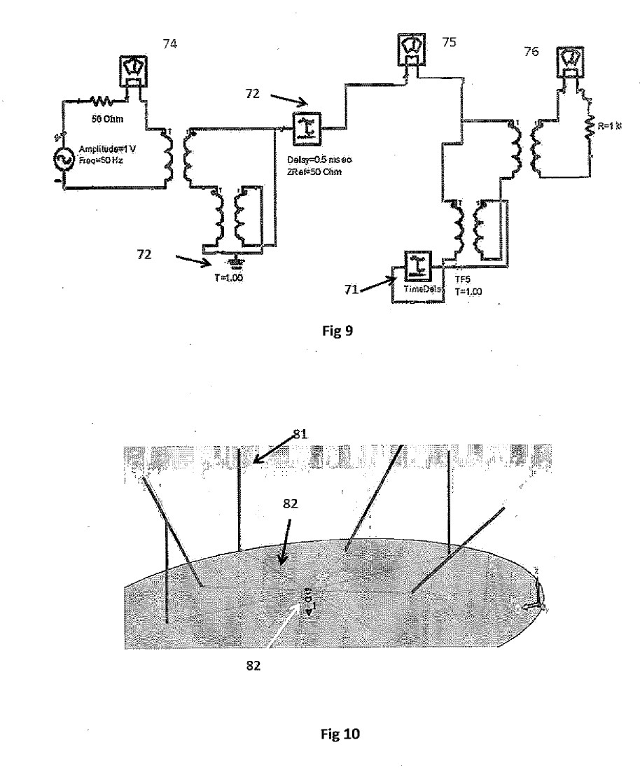

FIG. 10 shows air nullifier construction for simulation on frequency 1 MHz, which eight monopoles 81 was used. This frequency was chosen because simulation programs antenna does not allow making simulation on frequencies of 50 or 60 Hz. In line with this has been reduced monopole length up to 1/300 of. Monopoles were located over the metal (grounded) surface diameter 300 cm or 1/100 of. All monopoles were connected by wires 82 to a common point of input signal 83.

FIG. 11 shows a scheme for checking of nullifier for potential zeroing. Here 101 is source, 102 is non grounded disc with diameter 3 m, 103 is one of monopoles, 104 is disc with monopoles. When switch 105 is closed current must go in nullifier. Here resistor 106 which includes ampermeter and resistor 107 (50 Ohm) is resistor of source. As in case of antennas current cannot exit from monopole, therefore we have current zeroing in end of monopoles. Potential in point which connected with nullifier is zeroing too, because sum of voltage on nullifier and on scheme resistances is approximately equals to source voltage. The value is +3.5 Ohm speaks that the nullifier with compensation.

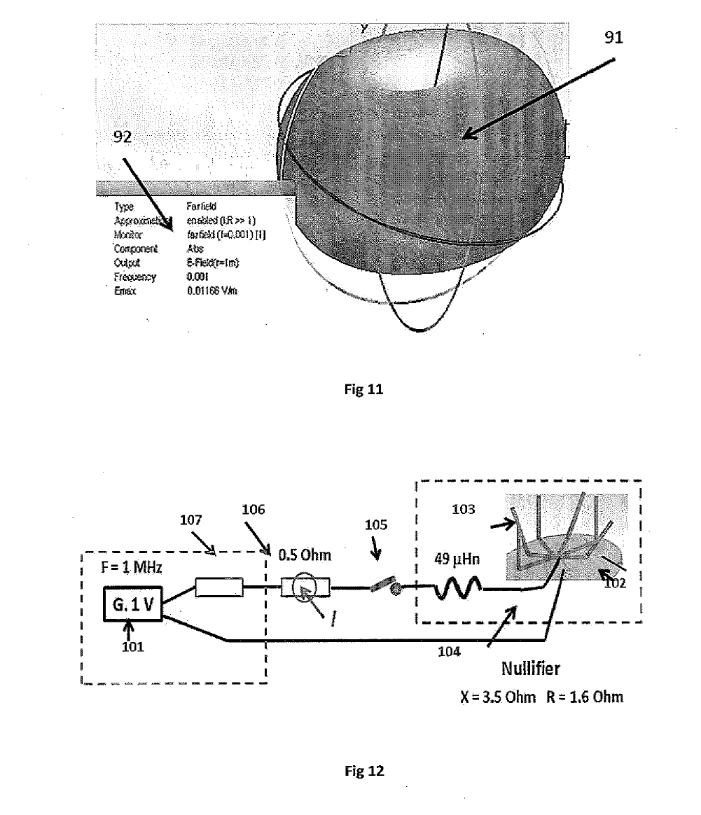

FIG. 12 shows simulation results of air nullifier on FIG. 10 on frequency 1 MHz, Where 91 is field strength at a distance of 1 m. The simulation showed 92 that the active radiation resistance is 0.02 Ohms and reactance is −309.4 Om. As expected a large value of negative reactance was obtained because of the small number of monopolies. That is, this construction requires compensation by inductance. But if you disable nullifier by switch, the current must have sharply reduced. In this case, the potential cannot be zeroed.

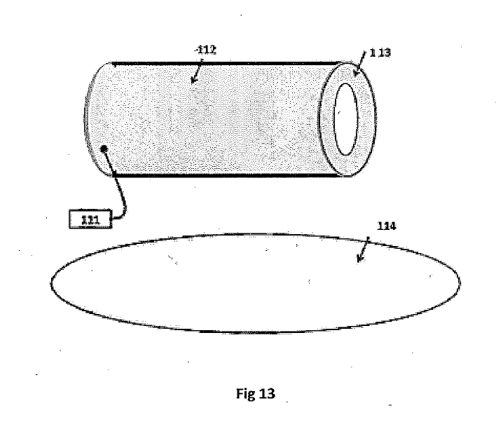

FIG. 13 shows a discharger for DC potential. For reducing a potential of the signal of a device operating with direct current 111 can be reduced in a process of discharge of static electricity. For reducing a potential of direct current it is proposed to use a cylinder or pipe 112 with a length of approximately 1 meter or more and with a thickness of approximately 10 cm and more, composed of a current conductive material 113. The cylinder can be closed by two metallic discs. The cylinder does not need to have a contact with a layer of Earth 114.

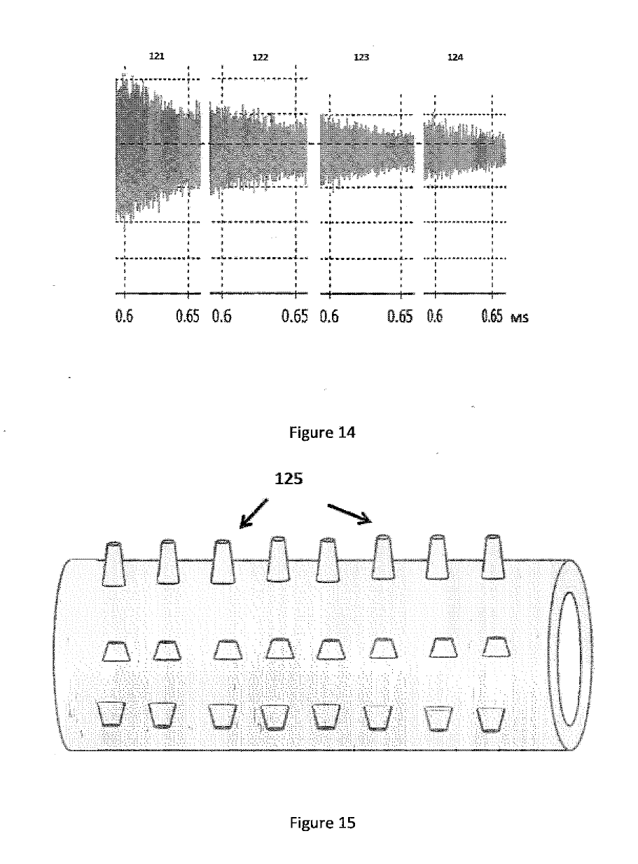

FIG. 14 shows the results of stimulation of a discharge process in the inventive method and system shown in FIG. 13. After termination current cylinder is discharged through a large (10K) resistance. The reduction of current, due to discharging, depending on the size of the cylinder indicates on the self-discharge static potential of cylinder. The cylinder is made of a conductive material not very high conductivity, where 121 is results when cylinder has length 1 m, outer diameter—60 cm, wall thickness—15 cm; 122 is results when cylinder has length 1 m, outer diameter—60 cm, wall thickness—15 cm; 123 is results when cylinder has length 2 m, outer diameter—60 cm, wall thickness—15 cm; 124 is results when cylinder has length 2 m, outer diameter—60 cm, wall thickness—15 cm and cylinder closed by two metallic discs. During the process of stimulation direct voltage was supplied, and its supply was stopped in 0.5 milliseconds. As can be seen from this figure, the discharge corresponds to cylinder dimensions. When instead of cylinder we used wire, the current in the same time was zero, because wire cannot have noticeable static electricity.

FIG. 15 shows an electrically conductive element which is formed as a hollow, preferably, cylindrical element, differently from the electrically conductive element of FIG. 13. In order to improve a process of static electricity discharge it can be provided with projections 125 on its outer surface.

It should be mentioned that the systems shown in FIGS. 1-4 and 8-12 are preferably used as nullifiers for alternating current, the systems shown in FIGS. 13-15 are preferably used as dischargers for direct current, and the systems shown in FIGS. 5, 6 and 7 can be used for both.

What is desired to be protected by Letters Patent is set forth in particular in the appended claims:

1. A method of reducing an electrical potential of an electrical system or of an electrical device, comprising the steps of electrically connecting one part of an electrically conducting element to an electrical system or an electrical device having an electrical potential, and extending the electrically conducting element so that its another part is introduced in a medium other than a layer of Earth.
The method of claim 1, wherein introducing the another part of the electrically conducting element in a medium other than a layer of Earth includes arranging the other part of the electrically conductive element so that it is electrically isolated from the ground of the layer of Earth.
The method of claim 1, wherein introducing the another part is introduced in a medium other than a layer of Earth includes arranging the other part of the electrically conductive element so that it extends in one direction.
The method of claim 1, wherein introducing the another part in a medium other than a layer of Earth includes arranging the other part of the electrically conductive element so that it extends in a plurality of directions.
The method of claim 1, wherein the electrically conducting element is an element is selected from the group consisting of an electrically conductive wire and an electrically conductive rod.
The method of claim 1, wherein the electrically conducting element has a length which is much shorter than a quarter electrical wavelength of an electrical current whose potential is reducing or zeroing.
The method of claim 1, wherein the electrically conducting element is provided with an inductance between its one part and its another part.
The method of claim 1, wherein the electrically conducting element includes a delay line shifting a phase of the electric current by 180 degrees or a number of 180 degrees and having an output connectable with a point for zeroing.
The method of claim 1, wherein the extending the electrically conducting element so that its another part is introduced in a medium other than a layer of Earth includes using as the medium a ground, or grains of a semiconducting material which can be composed of sand particles.
The method claim 1, wherein for zeroing of a potential of a static electricity the electrically conducting element is formed as a hollow element with or without protrusions on its surface.
A system for reducing or even zeroing an electrical potential of an electrical system or of an electrical device, comprises an electrically conducting element which has one part electrically connectable to an electrical system or an electrical device having an electrical potential, and extends so that its another part is introduced in a medium other than a layer of Earth.
A system of claim 11, wherein the electrically conducting element extends so that its another part is introduced in a medium other than a layer of Earth and is electrically isolated from the ground of Earth.
A system of claim 11, wherein the electrically conducting element is configured so that its another part is introduced in a medium other than a layer of Earth and it extends in one direction.
A system of claim 11, wherein the electrically conducting element is configured so that its another part is introduced in a medium other than a layer of Earth and is arranged so that the other part of the electrically conductive element extends in a plurality of directions.
A system of claim 11, wherein the electrically conducting element is an element selected from the group consisting of an electrically conductive wire and an electrically conductive rod.
A system of claim 11, wherein the electrically conducting element has a length substantially smaller than a quarter electrical wavelength of an electrical current whose potential is zeroing.
A system of claim 11, wherein the electrically conducting element provided with an inductance between its one part and its another part.
A system of claim 11, wherein the electrically conducting element includes a delay line shifting a phase of the electric current by 180 degrees or a number of 180 degrees.

19. A system of claim 11, wherein the electrically conducting element is configured so that its another part is introduced in a medium which is other than a ground of the layer of Earth and includes grains of a semiconducting material which can be composed of sand particles.

20. A system of claim 11, wherein the electrically conducting element is hollow and formed with or without protrusions of its outer surface.
